(19) United States
(12) Patent Application Publication
(10) Pub. No.: US 2020/0284851 A1
(43) Pub. Date: Sep. 10, 2020

(54) METHOD AND SYSTEM FOR PREDICTING ELECTRODE SHORT CIRCUIT BASED ON CURRENT

(71) Applicant: NORTH CHINA UNIVERSITY OF TECHNOLOGY, BEIJING (CN)

(72) Inventors: JUN TIE, BEIJING (CN); RENTAO ZHAO, BEIJING (CN); ZHIFANG ZHANG, BEIJING (CN); WENTANG ZHENG, BEIJING (CN)

(21) Appl. No.: 16/461,233

(22) PCT Filed: Jun. 27, 2018
(86) PCT No.: PCT/CN2018/093015

§ 371 Date: May 15, 2019

(30) Foreign Application Priority Data
Mar. 15, 2018 (CN) 201810214300.8

(51) Int. Cl. G01R 31/52; C25D 17/00; C25D 21/12

(52) U.S. Cl. CPC G01R 31/52; C25D 21/12; C25D 17/005

(57) ABSTRACT

A method for predicting an electrode short circuit based on a current includes acquiring a current value of a cathode of an anode-cathode pair; acquiring a plurality of current values during a set period of time; determining an increased value of the plurality of current values varying with time; determining whether the increased value is within a set current range; if yes, using a linear fitting method to fit the plurality of current values in time sequence to obtain a linear model; acquiring a slope and a determining coefficient of the linear model; determining whether the slope is within a set slope range; if yes, determining whether the determining coefficient is smaller than a set determining coefficient value; if no, determining that there is a short circuit danger in the electrodes of the anode-cathode pair, and in other cases, determining that there is no short circuit danger in the electrodes.

### CROSS REFERENCE TO RELATED APPLICATIONS

This application claims priority to PCT application PCT/CN2018/093015 filed Jun. 27, 2018, which claims priority to Chinese application number 201810214300.8 filed Mar. 15, 2018; the disclosure of each is incorporated herein in its entirety by reference.

### FIELD OF THE DISCLOSURE

The disclosure relates generally to the field of aqueous solution electrolysis. More specifically, the disclosure relates to the field of a method and system for predicting an electrode short circuit based on a current.

### BACKGROUND

In industrial production processes such as electrolytic refining and electrolytic deposition of aqueous solutions of metals such as copper, lead, zinc, nickel and manganese, a single electrolytic cell generally contains tens of anodes and a corresponding number of cathodes, and anode plates and cathode plates are cross side by side. The anode and the cathode of the electrolytic cell are both in the shape of a plate and are thus called an anode plate and a cathode plate, with the area of each single face being 1 m² or more. The single electrode plate allows a current of 500 A or more to pass. Due to the narrow space between the anode plate and the cathode plate on the electrolytic cell and an electrode distance of dozens of millimeters, local deformation on the electrode surface may cause uneven distribution of a current on the electrode surface, resulting in an increase in local current density. Proportion or component disorder of additives in the electrolytic process leads to dendrites formation on the surface of the electrode plate. Some components of the anode used for refining exceed the requirements, resulting in the formation of agglomerates on the surface of the corresponding cathode. The occurrence of these conditions will cause localized formation of the agglomerates on the surface of the cathode and the agglomerates will gradually grow into coarse particles. When the particles are in contact with the surface of the anode, a short circuit will be formed between the cathode and the anode, which not only lowers current efficiency, but also reduces the cathode quality, and even causes serious situations such as burning and deformation of the cathode plate and a current conducting rod.

Currently, for the short circuit between the cathode and the anode, infrared imaging detection, drag meter detection, and water spray detection and the like are generally adopted. These methods may be used to detect the occurrence of the short circuit under the conditions of remarkable heating of the conductive end of the cathode after the short circuit has been formed between the anode and the cathode, and then the short circuit is cleaned. Consequently, when the short circuit is detected, the current loss and the reduction in cathode quality have been brought about.

### SUMMARY

The following presents a simplified summary of the invention in order to provide a basic understanding of some aspects of the invention. This summary is not an extensive overview of the invention. It is not intended to identify critical elements or to delineate the scope of the invention. Its sole purpose is to present some concepts of the invention in a simplified form as a prelude to the more detailed description that is presented elsewhere.

In some embodiments, an objective is to provide a method and system for predicting an electrode short circuit based on a current, to solve the problems of current losses and the reduction in cathode quality when a short circuit between a cathode and an anode is detected by using the current technology. By predicting the short circuit of an electrode, a hidden danger of the short circuit is determined in advance to avoid the current losses and improve the quality of the cathode.

According to an embodiment, a method for predicting an electrode short circuit based on a current may include the following steps. (1) Obtaining a current value of a cathode of an anode-cathode pair acquired by a current acquisition device. (2) Acquiring a plurality of current values of the cathode in the anode-cathode pair during a set period of time. (3) Determining an increased value of the plurality of current values varying with time. (4) Determining whether the increased value of the plurality of current values varying with time is within a set current range to obtain a first determining result. (5) Determining, when the first determining result indicates that the increased value of the plurality of current values varying with time is not within the set current range, that there is no short circuit danger in the electrodes of the anode-cathode pair. (6) Using, when the first determining result indicates that the increased value of the plurality of current values varying with time is within the set current range, a linear fitting method to fit the plurality of current values in time sequence to obtain a linear model. (7) Acquiring a slope and a determining coefficient of the linear model. (8) Determining whether the slope is within a set slope range, to obtain a second determining result. (9) Determining, when the second determining result indicates that the slope is not within the set slope range, that there is no short circuit danger in the electrodes of the anode-cathode pair. (10) Determining, when the second determining result indicates that the slope is within the set slope range, whether the determining coefficient is smaller than a set determining coefficient value, to obtain a third determining result. (11) Determining, when the third determining result indicates that the determining coefficient is smaller than the set determining coefficient value, that there is no short circuit danger in the electrodes of the anode-cathode pair. (12) Determining, when the third determining result indicates that the determining coefficient is not smaller than the set determining coefficient value, that there is a short circuit danger in the electrodes of the anode-cathode pair.

According to another embodiment, a sampling period of the current acquisition device is less than 5 minutes, and the set time period is 100 minutes.

According to a further embodiment, determining an increased value of the plurality of current values varying with time may include the following steps. (1) Sorting the plurality of current values according to a collection time to obtain a sorted current value sequence. (2) Acquiring a difference between a last current value and a first current value in the current value sequence. (3) Determining the difference as the increased value of the plurality of current values varying with time.

According to an alternate embodiment, the set current range is 10-60 A.

In some embodiments, the set slope range is 0.10-0.60 A/min, and the set determining coefficient value is 0.7.

In other embodiments, after determining that there is the short circuit danger in the electrodes of the anode-cathode pair, the method may further include generating alarm information indicating that the electrode has a short circuit danger, to remind workers to perform processing.

In further embodiments, a system for predicting an electrode short circuit based on a current may include: (1) a current value obtaining module, configured to obtain a current value of a cathode of an anode-cathode pair acquired by a current acquisition device, and acquire a plurality of current values of the cathode in the anode-cathode pair during a set period of time; (2) an increased value determining module, configured to determine an increased value of the plurality of current values varying with time; (3) a first determining module, configured to determine whether the increased value of the plurality of current values varying with time is within a set current range to obtain a first determining result; (4) a module for determining no short circuit danger in electrodes, configured to, when the first determining result indicates that the increased value of the plurality of current values varying with time is not within the set current range, determine that there is no short circuit danger in the electrodes of the anode-cathode pair; (5) a linear fitting module, configured to, when the first determining result indicates that the increased value of the plurality of current values varying with time is within the set current range, use a linear fitting method to fit the plurality of current values in time sequence to obtain a linear model; (6) a slope and determining coefficient acquisition module, configured to acquire a slope and a determining coefficient of the linear model; (7) a second determining module, configured to determine whether the slope is within a set slope range, to obtain a second determining result; where the module for determining no short circuit danger in electrodes is further configured to, when the second determining result indicates that the slope is not within the set slope range, determine that there is no short circuit danger in the electrodes of the anode-cathode pair; (8) a third determining module, configured to, when the second determining result indicates that the slope is within the set slope range, determine whether the determining coefficient is smaller than a set determining coefficient value, to obtain a third determining result; where the module for determining no short circuit danger in electrodes is further configured to, when the third determining result indicates that the determining coefficient is smaller than the set determining coefficient value, determine that there is no short circuit danger in the electrodes of the anode-cathode pair; and (9) a module for determining a short circuit danger in electrodes, configured to, when the third determining result indicates that the determining coefficient is not smaller than the set determining coefficient value, determine that there is a short circuit danger in the electrodes of the anode-cathode pair.

In alternate embodiments, the increased value determining module may include: (1) a sorting unit, configured to sort the plurality of current values according to a collection time to obtain a sorted current value sequence; (2) a difference acquisition unit, configured to acquire a difference between a last current value and a first current value in the current value sequence; and (3) an increased value determining unit, configured to determine the difference as the increase value of the plurality of current values varying with time.

In embodiments, the system may further include an alarm information generating module, configured to, after it is determined that there is the short circuit danger in the electrodes of the anode-cathode pair, generate alarm information indicating that the electrode has a short circuit danger to remind workers to perform processing.

In some embodiments, by utilizing the linear increase characteristic exhibited by cathode surface particles before the cathode surface particles approach the surface of the anode, a change pattern of the cathode current may be analyzed through continuous measurement of the cathode current and the short circuit of the cathode may be predicted in a time period of about 100 min. Once this characteristic is found, it may be determined that there is a short circuit danger. In an hour or more before the short circuit occurs, early warning information may be given, thus prompting workers to perform short circuit danger treatment, thereby avoiding the subsequent occurrence of the short circuit and eliminating the current losses and other damage caused by the short circuit. Other embodiments of the invention may provide novel technology and methods to improve electrolytic current efficiency and product quality, and reduce product cost.

In various embodiments of the current disclosure, the presence of coarse particles on the surface of the cathode may be effectively determined, the danger may be found before the occurrence of the short circuit, the electrolysis current efficiency and product quality may be significantly improved, and the product cost may be reduced.

### BRIEF DESCRIPTION OF THE DRAWINGS

Illustrative embodiments of the present disclosure are described in detail below with reference to the accompanying drawings.

FIG. 1 is a schematic flow chart of a method for predicting an electrode short circuit based on a current according to an embodiment.

FIG. 2 is a schematic structural view of a system for predicting an electrode short circuit based on a current according to another embodiment.

### DETAILED DESCRIPTION

The described embodiments are merely a part rather than all of the embodiments of the present invention. All other embodiments obtained by a person of ordinary skill in the art based on the embodiments of the present invention without creative efforts shall fall within the protection scope of the present invention.

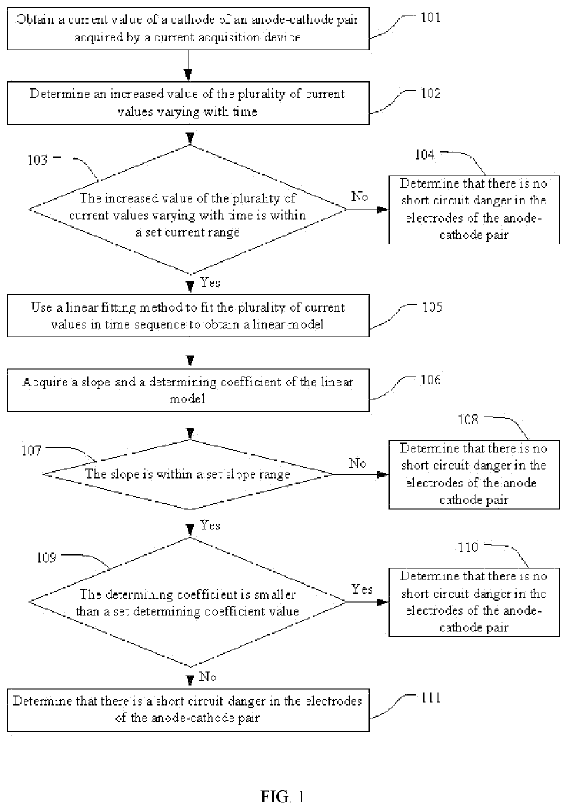

FIG. 1 is a schematic flow chart of a method for predicting an electrode short circuit based on a current according to an embodiment of the invention. As shown in FIG. 1, the method may include the following steps. Step 101: obtain a current value of a cathode of an anode-cathode pair acquired by a current acquisition device. Obtain a plurality of current values of the cathode in the anode-cathode pair during a set period of time. The current acquisition device collects data continuously, and a sampling period is less than 5 minutes, that is, sampling is performed at least once every 5 minutes. The set time period is 100 minutes, which is a time period obtained after a lot of experiments and analysis. During the set time period, an overall prediction result is more accurate. Step 102: determine an increased value of the plurality of current values varying with time. The process of determining the increased value of the plurality of current values varying with time is as follows: the plurality of current values are sorted according to a collection time to obtain a sorted current value sequence; and a difference between a last current value and a first current value in the current value sequence is obtained; and the difference is determined as the increase value of the plurality of current values varying with time, and the increase value is a positive value at this time. Step 103: determine whether the increased value of the plurality of current values varying with time is within a set current range; if not, execute step 104; and if yes, execute step 105. The set current range is a positive value, and may be set to 10-60 A. Step 104: determine that there is no short circuit danger in electrodes of the anode-cathode pair. Step 105: use a linear fitting method to fit the plurality of current values in time sequence to obtain a linear model. Step 106: acquire a slope and a determining coefficient of the linear model. Step 107: determine whether the slope is within a set slope range. If not, execute step 108; and if yes, execute step 109. The set slope range is usually 0.10-0.60 A/min. Step 108: determine that there is no short circuit danger in the electrodes of the anode-cathode pair.

Step 109: determine whether the determining coefficient is smaller than a set determining coefficient value; if yes, execute step 110; and if not, execute step 111. The set determining coefficient value of this embodiment may be 0.7. Step 110: determine that there is no short circuit danger in the electrodes of the anode-cathode pair. Step 111: determine that there is a short circuit danger in the electrodes of the anode-cathode pair. When the third determining result is yes, it indicates that coarse particles are grown on the surface of the cathode and will be in contact with the anode, and there is a short circuit danger. After it is determined that there is the short circuit danger in the electrodes of the anode-cathode pair, alarm information indicating that the electrode has a short circuit danger is generated to remind workers to perform processing to avoid the occurrence of a short circuit.

Before the implementation of some embodiments of the invention, through field testing and research, it has been found that a cathode current is information most sensitive to the short circuit occurrence process. The cathode current exhibits a very smooth mode during a normal electrolysis process. However, after the short circuit occurs, the current rapidly increases to three times the average current, and in the 3-4 h before the short circuit occurs, when the coarse particles generated on the surface of the cathode grow close to the anode and are 1-3 mm away from the anode surface, a significant change in the cathode current will be caused, presenting a linear increase pattern of 0.10 to 0.6 A/min. When the particles are in contact with the anode surface, the cathode current rapidly increases and oscillates until a stable circuit connection is formed with the anode, and the current reaches a maximum short circuit value.

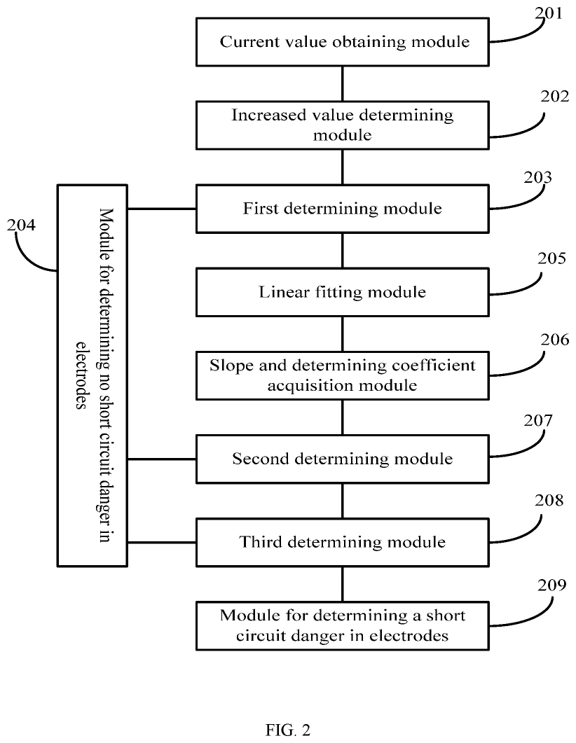

FIG. 2 is a schematic structural view of a system for predicting an electrode short circuit based on a current according to another embodiment of the invention. As shown in FIG. 2, the system may include: (1) a current value obtaining module 201, configured to obtain a current value of a cathode of an anode-cathode pair acquired by a current acquisition device, and acquire a plurality of current values of the cathode in the anode-cathode pair during a set period of time; (2) an increased value determining module 202, configured to determine an increased value of the plurality of current values varying with time; (3) a first determining module 203, configured to determine whether the increased value of the plurality of current values varying with time is within a set current range to obtain a first determining result; (4) a module 204 for determining no short circuit danger in electrodes, configured to, when the first determining result indicates that the increased value of the plurality of current values varying with time is not within the set current range, determine that there is no short circuit danger in the electrodes of the anode-cathode pair; (5) a linear fitting module 205, configured to, when the first determining result indicates that the increased value of the plurality of current values varying with time is within the set current range, use a linear fitting method to fit the plurality of current values in time sequence to obtain a linear model; (6) a slope and determining coefficient acquisition module 206, configured to acquire a slope and a determining coefficient of the linear model; (7) a second determining module 207, configured to determine whether the slope is within a set slope range, to obtain a second determining result;

where the module 204 for determining no short circuit danger in electrodes is further configured to, when the second determining result indicates that the slope is not within the set slope range, determine that there is no short circuit danger in the electrodes of the anode-cathode pair; (8) a third determining module 208, configured to, when the second determining result indicates that the slope is within the set slope range, determine whether the determining coefficient is smaller than a set determining coefficient value, to obtain a third determining result; where the module 204 for determining no short circuit danger in electrodes is further configured to, when the third determining result indicates that the determining coefficient is smaller than the set determining coefficient value, determine that there is no short circuit danger in the electrodes of the anode-cathode pair; and (9) a module 209 for determining a short circuit danger in electrodes, configured to, when the third determining result indicates that the determining coefficient is not smaller than the set determining coefficient value, determine that there is a short circuit danger in the electrodes of the anode-cathode pair.

The increased value determining module 202 may include: (1) a sorting unit, configured to sort the plurality of current values according to a collection time to obtain a sorted current value sequence; (2) a difference acquisition unit, configured to acquire a difference between a last current value and a first current value in the current value sequence; and (3) an increased value determining unit, configured to determine the difference as the increase value of the plurality of current values varying with time.

The system may further include an alarm information generating module, configured to, after it is determined that there is the short circuit danger in the electrodes of the anode-cathode pair, generate alarm information indicating that the electrode has a short circuit danger to remind workers to perform processing.

Embodiments of the present specification may be described in a progressive manner; each embodiment focuses on the difference from other embodiments, and the same and similar parts between the embodiments may refer to each other.

The above embodiments are provided merely for the purpose of describing the present invention and are not intended to limit the scope of the present invention. Various equivalent replacements and modifications made without departing from the spirit and scope of the present invention should fall within the scope of the present invention.

Many different arrangements of the various components depicted, as well as components not shown, are possible without departing from the spirit and scope of the present disclosure. Embodiments of the present disclosure have been described with the intent to be illustrative rather than restrictive. Alternative embodiments will become apparent to those skilled in the art that do not depart from its scope. A skilled artisan may develop alternative means of implementing the aforementioned improvements without departing from the scope of the present disclosure.

It will be understood that certain features and subcombinations are of utility and may be employed without reference to other features and subcombinations and are contemplated within the scope of the claims. Unless apparent, inherent, or indicated otherwise, not all steps listed in the various figures need be carried out in the specific order described.

The disclosure claimed is:

1. A method for predicting an electrode short circuit based on a current, comprising:
obtaining a current value of a cathode of an anode-cathode pair acquired by a current acquisition device;
acquiring a plurality of current values of the cathode in the anode-cathode pair during a set period of time;
determining an increased value of the plurality of current values varying with time;
determining whether the increased value of the plurality of current values varying with time is within a set current range to obtain a first determining result;
determining, when the first determining result indicates that the increased value of the plurality of current values varying with time is not within the set current range, that there is no short circuit danger in the electrodes of the anode-cathode pair;
using, when the first determining result indicates that the increased value of the plurality of current values varying with time is within the set current range, a linear fitting method to fit the plurality of current values in time sequence to obtain a linear model;
acquiring a slope and a determining coefficient of the linear model;
determining whether the slope is within a set slope range, to obtain a second determining result;
determining, when the second determining result indicates that the slope is not within the set slope range, that there is no short circuit danger in the electrodes of the anode-cathode pair;
determining, when the second determining result indicates that the slope is within the set slope range, whether the determining coefficient is smaller than a set determining coefficient value, to obtain a third determining result;
determining, when the third determining result indicates that the determining coefficient is smaller than the set determining coefficient value, that there is no short circuit danger in the electrodes of the anode-cathode pair; and
determining, when the third determining result indicates that the determining coefficient is not smaller than the set determining coefficient value, that there is a short circuit danger in the electrodes of the anode-cathode pair.

2. The method for predicting an electrode short circuit according to claim 1, wherein a sampling period of the current acquisition device is less than 5 minutes and the set period of time is 100 minutes.

3. The method for predicting an electrode short circuit according to claim 1, wherein the determining the increased value of the plurality of current values varying with time comprises:
sorting the plurality of current values according to a collection time to obtain a sorted current value sequence;
acquiring a difference between a last current value and a first current value in the current value sequence; and
determining the difference as the increased value of the plurality of current values varying with time.

4. The method for predicting an electrode short circuit according to claim 1, wherein the set current range is 10-60 A.

5. The method for predicting an electrode short circuit according to claim 1, wherein the set slope range is 0.10-0.60 A/min, and the set determining coefficient value is 0.7.

6. The method for predicting an electrode short circuit according to claim 1, wherein after determining that there is the short circuit danger in the electrodes of the anode-cathode pair, the method further comprises:
generating alarm information indicating that the electrode has a short circuit danger, to remind workers to perform processing.

7. A system for predicting an electrode short circuit based on a current, comprising:
a current value obtaining module, configured to obtain a current value of a cathode of an anode-cathode pair acquired by a current acquisition device, and acquire a plurality of current values of the cathode in the anode-cathode pair during a set period of time;
an increased value determining module, configured to determine an increased value of the plurality of current values varying with time;
a first determining module, configured to determine whether an increased value of the plurality of current values varying with time is within a set current range to obtain a first determining result;
a module for determining no short circuit danger in electrodes, configured to, when the first determining result indicates that the increased value of the plurality of current values varying with time is not within the set current range, determine that there is no short circuit danger in the electrodes of the anode-cathode pair;
a linear fitting module, configured to, when the first determining result indicates that the increased value of the plurality of current values varying with time is within the set current range, use a linear fitting method to fit the plurality of current values in time sequence to obtain a linear model.
a slope and determining coefficient acquisition module, configured to acquire a slope and a determining coefficient of the linear model;
a second determining module, configured to determine whether the slope is within a set slope range, to obtain a second determining result;
wherein the module for determining no short circuit danger in electrodes is further configured to, when the second determining result indicates that the slope is not within the set slope range, determine that there is no short circuit danger in the electrodes of the anode-cathode pair;
a third determining module, configured to, when the second determining result indicates that the slope is within the set slope range, determine whether the determining coefficient is smaller than a set determining coefficient value, to obtain a third determining result;
wherein the module for determining no short circuit danger in electrodes is further configured to, when the third determining result indicates that the determining coefficient is smaller than the set determining coefficient value, determine that there is no short circuit danger in the electrodes of the anode-cathode pair; and
a module for determining a short circuit danger in electrodes, configured to, when the third determining result indicates that the determining coefficient is not smaller than the set determining coefficient value, determine that there is a short circuit danger in the electrodes of the anode-cathode pair.

8. The system for predicting an electrode short circuit according to claim 7, wherein the increased value determining module comprises:
a sorting unit, configured to sort the plurality of current values according to a collection time to obtain a sorted current value sequence;
a difference acquisition unit, configured to acquire a difference between a last current value and a first current value in the current value sequence; and
an increased value determining unit, configured to determine the difference as the increase value of the plurality of current values varying with time.

9. The system for predicting an electrode short circuit according to claim 7, further comprising:
an alarm information generating module, configured to, after it is determined that there is the short circuit danger in the electrodes of the anode-cathode pair, generate alarm information indicating that the electrode has a short circuit danger to remind workers to perform processing.
